(19) United States
(12) Patent Application Publication
(10) Pub. No.: US 2014/0043059 A1
(43) Pub. Date: Feb. 13, 2014

(54) SECURE DIGEST FOR PLD CONFIGURATION DATA

(71) Applicant: Microsemi SoC Corp., San Jose, CA (US)

(72) Inventors: Theodore Speers, San Jose, CA (US); G. Richard Newell, El Sobrante, CA (US)

(73) Assignee: Microsemi SoC Corp., San Jose, CA (US)

(21) Appl. No.: 13/964,692

(22) Filed: Aug. 12, 2013

Related U.S. Application Data
(60) Provisional application No. 61/682,123, filed on Aug. 10, 2012.

(51) Int. Cl. H03K 19/003

(52) U.S. Cl. CPC H03K 19/003
USPC 326/9

(57) ABSTRACT

A method for verifying that data is correctly loaded into an individual programmable logic device includes computing a reference digest of the data to be loaded into the individual programmable logic device, loading the data into the individual programmable logic device, computing inside the individual programmable logic device an as-programmed digest of the data that was loaded into the individual programmable logic device, reading the as-programmed digest out of the individual programmable logic device, comparing the as-programmed digest with the reference digest, and verifying the loaded data if the as-programmed digest matches the reference digest, and indicating an error if the as-programmed digest does not match the reference digest.

### BACKGROUND

1. Field of the Invention

The present invention relates to programmable integrated circuits such as field-programmable gate array (FPGA) integrated circuits and other programmable logic device (PLD) integrated circuits. More particularly, the present invention relates to verifying data that is loaded into programmable logic devices.

2. The Prior Art

FPGA and other PLD devices can be programmed from external sources using configuration bit streams. In addition, cryptographic keys and other sensitive data (IP) are loaded into such devices from external sources.

In the prior art known to the inventors, cryptographic keys, configuration bitstreams, and other sensitive data had to be programmed into the FPGA or PLD (or its external configuration non-volatile memory) by a trusted party in a trusted environment. While, for the most part, this has been a reliable procedure, it is not completely secure. For example, a malicious agent could program in its own keys, and having done this, it could load an encrypted IP of their choosing using those keys. This would allow the introduction of a Trojan horse or other malware into the FPGA or other PLD, defeating any security there might have been. New devices are especially vulnerable, since they are shipped from the component manufacturer in an unlocked state that allows whoever first programs them to load whatever user keys or security settings or IP they want.

Without physically retrieving the parts from the provisioner and running a bitstream verification procedure in a trusted environment, it is difficult for the original equipment manufacturer (OEM) to discover whether or not the correct IP (and keys) had been loaded properly. Such a procedure would be prohibitively expensive and would unreasonably increase the cost of using FPGA and other PLD devices.

As an example, some flash-based FPGA devices have multiple Flash memory segments. One or more security-oriented segments hold the keys and lock-bits, while other segments are associated with configuring the FPGA logic and still others store bulk data such as firmware in non-volatile memory arrays. Lock-bits in each segment secure that segment. An associated passcode is required to override this lock-bit to allow any changes.

The issue to be addressed is to be sure that the data loaded in the FPGA is that which was authorized. This includes assuring that Keys and Passcodes are as desired and not other keys, that security settings are configured as desired and that no loopholes have been left open, that configuration bitstreams loaded into the integrated circuit are as desired, e.g., no extraneous matter, Trojan horses, etc., have been added. This may include the programming of embedded non-volatile memory (eNVM) which could contain critical software code, end-application cryptography keys, etc.

In FPGAs based on a non-volatile memory technology such as Flash, these various types of data may all be configured and stored in the FPGA itself, whereas in FPGAs based mainly on a volatile memory technology such as SRAM, part of the data, e.g., the keys and some security settings, may be configured and stored in a small non-volatile memory in the FPGA, possibly based on one-time programmable fuse or anti-fuse technology, with most of the data stored in an external non-volatile memory that may be encrypted and/or authenticated using the same keys as stored in the FPGA. Even though the non-volatile memory is distributed between more than one device, the fundamental issue is still to ensure that the provisioner configures the system as a whole according to the wishes of the OEM.

### BRIEF DESCRIPTION

The present invention solves two main problems. First, it ensures that a provisioner contracted to program certain contents into FPGAs and other PLD devices and the associated external memories has done so according to the manufacturer's request, and has not a) made an error, or b) maliciously substituted some other data (for example, a bitstream containing a Trojan Horse, or cryptographic keys of its own choosing). This is done in such a way as to maintain the confidentiality of the original data, and without overly onerous logistical complications (such as requiring physical access to devices in a trusted environment). Key Files and Bitstreams (including security bit settings) may be encrypted and authenticated.

Another feature of the present invention is that it allows for the contents of the PLD to be verified from time to time without needing access to the full original bitstream. The PLD computes a short digest of associated PLD contents as each segment is locked down. A digest can be requested at any time, as an integrity/anti-tamper check. A PLD Digest is generated after the device is partially or fully programmed and the corresponding memory is locked. The requested digest can be compared internally with a stored digest of the same contents, as a type of built-in self test (BIST), or exported and compared externally with a reference digest.

Once locked down, the associated data cannot be changed, although in some implementations knowledge of a secret key used to override the lock that is not shared with the Vendor may allow reprogramming. The Programming provisioner (vendor) can be required to submit the digests to its customer as proof that no tampering has occurred with the PLD contents. Depending upon the specific use, the digests may be keyed, or not. A keyed, or “encrypted,” digest is used when the security objective includes prevention of forgery. An encrypted digest is often referred to as a message authentication code (MAC).

The customer (manufacturer or OEM) can compute a reference digest off line, and compare it to the digest the provisioner returns, to verify that the part was programmed with the requested data.

Digests can also be run periodically to check for integrity and tampering, with the results potentially used to trigger an anti-tampering penalty, or to notify another part of the system which can then take an appropriate action that enhances the overall system reliability, safety, or security. The PLD can be commanded to calculate a digest of its contents as a type of built-in self-test (BIST). This can be accomplished by a state machine or other processor or controller fabricated as part of the circuit that responds to an internal or external command. Such circuits are well known in the art. Of course, only the digest of the contents, and not the contents themselves, can be read out, since one object is to keep the configuration data confidential. A cryptographically strong hash function is preferably used, for pre-image and second pre-image resistance (in particular), and also for collision resistance. The digest can be used to certify that the device was loaded with the desired data, to detect tampering, single event upset (SEU) errors, end-of-life errors, or any other type of error.

In an example, an FPGA is divided into logical sections. The sections include the eNVM, the FPGA fabric configuration bits (possibly in multiple sections), the system controller firmware ROM, pre-defined groupings of security row bits, and others without limitation, which in total comprise all ROM, PROM, and RAM in the device. The digest can include any or all of the sections, upon request. The digests for each section are logically combined (e.g., XOR'd or hashed together) and the result may be keyed, as with a message authentication code (MAC). The key used should be known to the OEM and not to the provisioning vendor so the OEM can verify the MAC, but the vendor cannot forge it. Algorithms for computing encrypted/keyed digests, or message authentication codes, are well known in the art.

The digest can be used to certify the device was loaded properly. The FPGA computes an encrypted digest (i.e., MAC) of data stored in selected portions of the device and can concatenate the MAC with other information such as the device serial number to create a certificate which is then returned to the user. The electronic design automation (EDA) software can compute the expected encrypted digest for the same selected portions. Different actors (e.g., the manufacturer, the end user) can select different portions depending upon their role, what they know, and their objective. For example, the device manufacturer can use this method to ensure that those segments which are configured in its factory, such as that containing the device serial number, are programmed correctly; then after the parts are shipped to the provisioner, the end user can ensure the segments he controls are programmed correctly. Some sections may even be programmed on behalf of the customer's customer at the same or a later time, and the customer's customer then use this method to assure his data was programmed correctly.

In practice, portions of the data, such as the FPGA fabric, may be programmed the same for many devices. Therefore, the digest algorithm may be designed so that the EDA software only has to compute the digest for the repeat portion a single time. The certificate can be compared to the expected result to confirm that the device was programmed correctly. For a meaningful (i.e., unforgeable) certificate, something unique, such as the serial number, should be included in the sections selected for inclusion in the digest, otherwise, the MAC would be the same for all devices. The serial number and all other sections included (e.g., FPGA configuration data) should be locked and the lock bits also included in the digest so that the user can be assured the part was locked at the time the valid certificate was generated and thus the locked sections cannot be reprogrammed, for if they could be reprogrammed after the certificate was generated without the user's knowledge, it would nullify the value of the certificate.

To detect tampering, or natural errors such as SEU errors, the reference digest calculation may be done using the EDA software, which may be part of a programming hardware/software system and could include a hardware security module (HSM) or other processor. In this case, all of the data in the sections included must be known by the EDA software, or more generally, the programming system. Alternatively, a digest calculated earlier by the FPGA can be used as the reference, to look for changes in one computed later. In this case, sections containing data unknown to the end user, such as factory installed keys, can be included and changes will still be detected. It should be possible to initiate the digest calculation, and analyze the result in the FPGA fabric, even if the FPGA has to be halted or charge pumps turned on in order to read the configuration flash bits, so long as the result is presented to the fabric when it is restored to operation. Some PLDs (called customizable system-on-chips, or cSoCs) contain both FPGA elements and a microcontroller. The microcontroller may also be able to initiate the digest verification process, and respond to the result.

According to one aspect of the present invention, a cryptographic digest (or “hash”) algorithm is used to compress the contents of the FPGA or other PLD to a relatively short unique but unpredictable value that the provisioner would be required to report back to the OEM. This “certificate” provides verification to the OEM that the correct data had been loaded. The OEM can use the EDA software provided by the manufacturer to compute the same digest value off-line. If the off-line value matches the certificate returned by the provisioner, then the OEM could trust that the data in the FPGA or other PLD is identical to that used in the off-line procedure.

In flash-based FPGAs, like those manufactured by Microsemi Corporation of Aliso Viejo, Calif., assignee of the present invention, the certificate can be computed by the FPGA after the device has been locked against any future changes. Since every integrated circuit device can have a unique serial number, and that serial number can be included in the algorithm that produces the hash, the certificate will be unique for every individual integrated circuit device. If the OEM sends the provisioner “N” devices, and receives back “N” valid certificates for locked devices having those serial numbers, the OEM can be sure the devices were programmed correctly. Devices can be drop-shipped directly from the manufacturer or distributor to the provisioner, without having to go to a trusted location first, and the certificates will prove to the OEM that the devices were programmed according to its intention.

According to other aspects of the present invention, several variations are possible. First, the digest can be run against selected portions of the FPGA data, as opposed to all the data in the device. In some cases, the OEM may not know all the data. For example, the OEM would not know the manufacturer's factory keys, and thus these need to be excluded from any calculation that the OEM would run in its EDA tools. In some applications, the programming process may be performed in stages. In those applications, the digest may only be run against the latest data.

There is also the matter of computational efficiency. In practice, many FPGAs are often programmed with the same bitstream. Often, only the factory serial number and the keys are different, over a great many devices. The configuration bitstream for the FPGA fabric is the largest amount of data stored in the FPGA, so computing the digest in the EDA tool for this portion of the data would typically take the longest time. But, since this data is usually the same in the total population of FPGAs, it can be computed just once. This calculated digest for the configuration bitstream can then be used in the calculation of the final digest value for all the FPGAs by combining it with the digest for the other parts of the FPGA that may be unique in each device (such as the serial number). In one embodiment, if the FPGA fabric is included in a digest that is computed sequentially, the FPGA fabric data is then the first part of the total message being hashed.

Another enhancement, related to the above, is that the final digest value is encrypted, as with a MAC. It is essential that no one be able to predict the correct digest/certificate for any given device, otherwise a malicious agent could forge a “correct” digest value to be sent to the OEM, while the parts built are different. Making sure each digest is unique, such as by incorporating the device serial number, and encryption of the digest result, prevents this attack.

### BRIEF DESCRIPTION OF THE DRAWING FIGURES

FIG. 1 is a diagram showing an illustrative overview of the concepts of the present invention.

FIG. 2 is a diagram showing the operation of an illustrative embodiment of the present invention.

FIG. 3 is a flow diagram showing an illustrative embodiment of the present invention.

FIG. 4 is a flow diagram showing another illustrative embodiment of the present invention.

### DETAILED DESCRIPTION

Persons of ordinary skill in the art will realize that the following description of the present invention is illustrative only and not in any way limiting. Other embodiments of the invention will readily suggest themselves to such skilled persons.

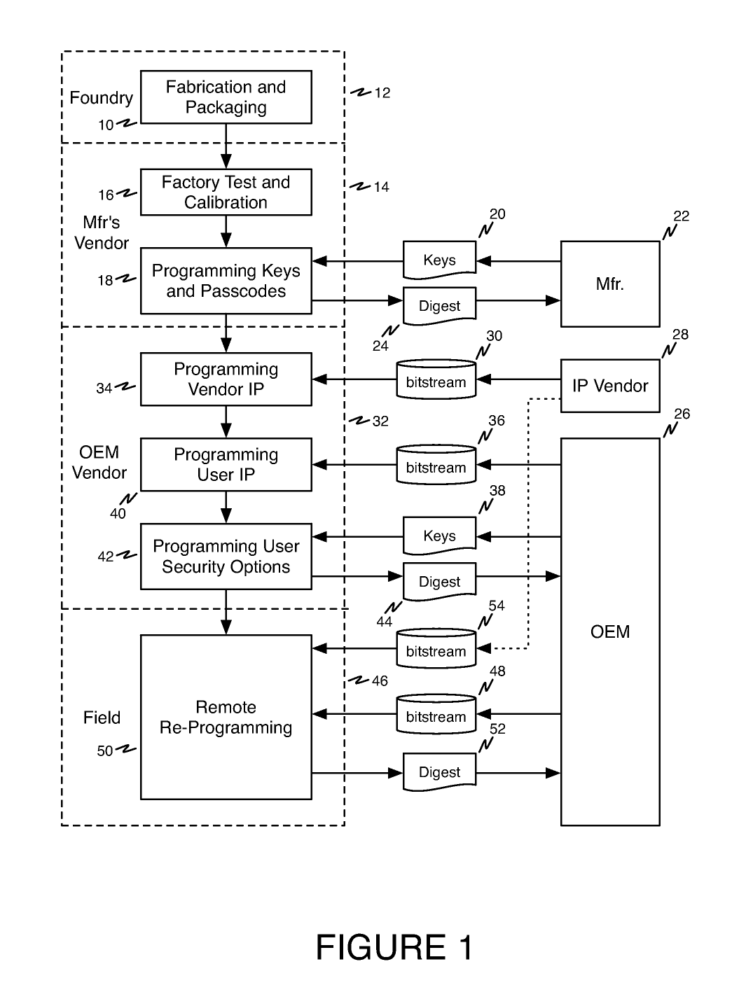

Referring first to FIG. 1, a diagram showing an overview of the present invention is presented. As indicated at reference numeral 10, a programmable integrated circuit device which may be a PLD such as an FPGA or other programmable device is fabricated and packaged, typically by a foundry engaged by the manufacturer and identified by reference numeral 12. A manufacturer's vendor, indicated at reference numeral 14, performs factory test and calibration operations at reference numeral 16 and then programs keys and passcodes as indicated at reference numeral 18. The key and passcode data 20 is supplied to the vendor 14 by manufacturer 22. Note that such data may be protected from inspection or tampering by the vendor using encryption, authentication, hardware security modules, or other means.

The manufacturer's vendor 14 returns a keyed digest (MAC) 24 to the manufacturer 22. The digest is a relatively short unique value that is generated by a cryptographic digest (or “hash”) algorithm used to compress the data contents of the FPGA or other PLD incorporating a secret key. The manufacturer 22 compares the generated digest 24 with an expected result to assure that the proper keys and passcodes were entered into the individual integrated circuit. An unkeyed digest may also be used as an on-the-spot check by the vendor that the contents have been programmed without error. This plaintext digest may or may not incorporate unique data, such as the device serial number, since the purpose of this digest is only to verify the integrity of the programmed data, and not to prevent forgeries of the digest, as with the keyed digest (or MAC).

The end-user of the individual programmable integrated circuit (OEM 26) often employs IP in the form of circuit configurations obtained from outside IP vendors. As shown in FIG. 1, IP Vendor 28 supplies bitstream data 30 for programming the vendor IP to OEM vendor 32, who programs that IP bitstream data into the individual integrated circuit as shown at reference numeral 34. The OEM 26 also supplies OEM programming bitstream data 36 and keys/passcodes for user security options shown at reference numeral 38 to OEM vendor 32 that are also programmed into the programmable integrated circuit as shown, respectively, at reference numerals 40 and 42. The OEM vendor 32 returns a keyed digest 44 to the OEM 26. The OEM 26 uses the digest 44 to assure that the proper keys, passcodes, vendor IP, and its own IP were entered correctly into the individual programmable integrated circuit.

Because many, programmable integrated circuits are reprogrammable, the present invention may also be used to verify re-programming operations that are made in the field identified by reference numeral 46. OEM 26 provides re-programming bitstream data 48 for remote reprogramming at reference numeral 50. A unique keyed digest of the re-programming operation, identified at reference numeral 52, is returned to the OEM 26. The OEM 26 uses the digest 52 to verify correct reprogramming of the programmable integrated circuit. Optionally, the IP vendor can provide re-programming bitstream data 54 for remote re-programming at reference numeral 50. The unique keyed digest 52 of the re-programming operation that is returned to the OEM 26 will include any vendor IP data.

According to the present invention, a cryptographic digest (or “hash”) algorithm is used to compress the data contents of the FPGA or other PLD into a relatively short unique but unpredictable value or “certificate” that the provisioner would be required to report back to the manufacturer or to the OEM. This digest is keyed, and as described above is often referred to as a MAC. The MAC is merged with other relevant data such as the public serial number to create a “certificate”. This certificate provides verification that the correct data has been loaded. The OEM or manufacturer can use the EDA software provided by the manufacturer to compute a reference digest for the same serial number as in the certificate. If the reference digest value matches the MAC in the certificate returned by the provisioner, then the OEM or manufacturer can trust that the data actually loaded into the FPGA or other PLD is identical to the reference data intended to be loaded into the device.

In flash-based FPGAs, the certificate can be computed by circuitry internal to the FPGA after the device has been locked against any future changes. Since every integrated circuit device can have a unique serial number, and that serial number can be included in the algorithm that produces the hash, the certificate will be unique for every individual integrated circuit device. If the OEM sends the provisioner “N” devices, and receives back “N” valid certificates for locked devices having those serial numbers, the OEM can be sure the devices were programmed correctly.

The method can also be applied to SRAM-based FPGAs that use non-volatile memory of any sort, such as one-time programmable (OTP) anti-fuse cells. A keyed digest can be computed for the data such as user keys and security lock-bits that are programmed into the non-volatile (e.g., OTP) memory. This keyed digest can be used to assure the end user that the provisioner programmed the correct data, such as user keys, into the devices. In SRAM-based FPGAs, these user keys are then used to authenticate and decrypt data stored in an external non-volatile memory that is loaded when the FPGA boots up when power is first applied or re-applied. The device can be designed to prevent operation using externally stored configuration data that is incorrect or has been tampered with, by authenticating the data using the user keys. Through this chain, starting by verifying the certificate generated when the nonvolatile data was programmed into the device, the end user can be reasonably assured that the FPGA will only execute the intended configuration data.

As will be appreciated by persons of ordinary skill in the art, there are numerous algorithms that are available to compute hash functions, any one of which would be suitable for use in the present invention. For example, the SHA-256 algorithm, as defined in National Institute of Standards and Technology (NIST) Federal Information Processing Standard (FIPS) 180-3 is a suitable unkeyed digest algorithm, and the hash-based MAC (HMAC) algorithm, based on SHA-256, as defined in NIST FIPS 198 is representative of a keyed digest, or message authentication code, as the terms are used herein. Other algorithms known in the art may alternatively be selected that provide better protection of the key against side channel analysis (SCA), such as differential power analysis (DPA) or differential electro-magnetic analysis (DEMA).

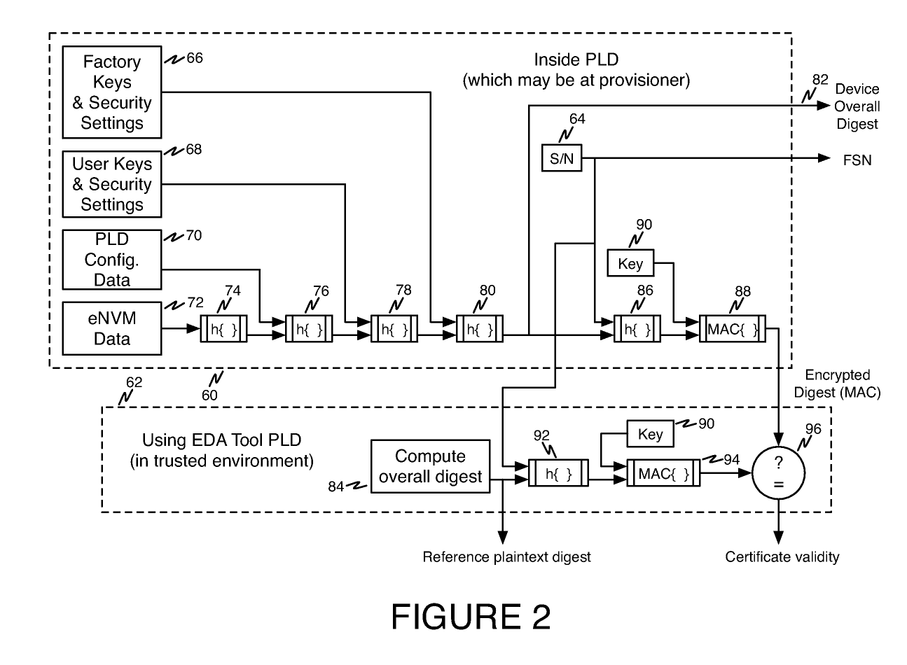

Referring now to FIG. 2, an illustrative example of the use of the present invention is shown. Persons of ordinary skill in the art will realize that the example of FIG. 2 is illustrative only and not limiting.

The operation of the invention within the individual PLD devices is shown within dashed rectangle 60 of FIG. 2. The operation of the invention in a controlled and trusted environment, such as an environment supported within either manufacturer 22 or OEM 26 of FIG. 1 is shown within dashed rectangle 62.

As previously noted, the data used to create the digest may include several components. In the example shown in FIG. 2, the components of the digest are the factory serial number (FSN), shown at reference numeral 64, the other factory keys or factory security settings such as lock bits shown at reference numeral 66, the user keys and security settings such as lock bits, and other user security data, shown at reference numeral 68, the eNVM configuration data, shown at reference numeral 70, and the PLD configuration data shown at reference numeral 72.

At reference numeral 74, a partial hash or digest h{ } is computed for the PLD data. At reference numeral 76, a partial hash or digest h{ } is computed from the eNVM data and the partial hash of the PLD configuration data 72. Note that the PLD configuration data 72 often constitutes the largest portion of the data needing digesting, and also that this part of the data is often constant across a whole population of PLDs. Thus, if this part of the computation can be shared across the whole population instead of recomputed for each device, computational resources can be saved. At reference numeral 78, a partial hash or digest h{ } is computed from the user keys, lock-bits, and other user security data and the partial hash that was computed from the eNMV data and the partial hash of the PLD configuration data at the output of reference number 76. At reference numeral 80, a partial hash or digest h{ } is computed from the factory keys, lock-bits, and other security settings and the partial hash computed at reference numeral 78. The output of reference number 80 constitutes the device overall digest. Persons of ordinary skill in the art will recognize that the embodiment of FIG. 2 is illustrative and not limiting, and that there are multiple ways of computing and combining the partial hashes that are intended to fall within the scope of the present invention. As a non-limiting example, such skilled persons will appreciate that the partial hashes can be computed in parallel instead of in a chain fashion and may be combined using any of a number of suitable functions such as, but not limited to, hash functions, and the XOR function.

The overall digest may be output from the device as shown at reference numeral 82 for use by the vendor as a quick but unsecure check of the device contents by comparing it at reference numeral 84 to the reference plaintext digest shown as reference numeral 86, as supplied to the vendor by the OEM. At reference numeral 88 a partial hash is computed from the FSN uniquely stored in each device, represented by reference numeral 64 as indicated above, and the overall digest output indicated by reference numeral 82. This guarantees a unique digest for each device, even if up to this point the result (i.e., the overall digest) for a plurality of devices is the same, as may be the case, especially if not all sections are included.

Persons of ordinary skill in the art will readily understand that other partial or overall digests may be created in particular instances of the invention. Multiple keyed or plaintext digests may be computed at one time for different, the same, or overlapping sets of data. Such skilled persons will observe that any one of numerous available algorithms may be employed to compute the partial hashes or digests and that the digests may be calculated in parallel and then combined, or computed iteratively, as shown in the example.

The calculations may include all or just some of the data in the device. Particularly, if the data is programmed by different actors at different times, the digest computed at each time may only include the most recently programmed data, plus the serial number. It should be noted that if the reference digest is to be computed by a particular actor, such as the OEM user, then that actor must have knowledge of all the data incorporated. For example, the OEM would not know the factory keys, so this data would have to be left out of any reference digest he calculates, and therefore the device must also leave out this data when the purpose of the calculation is to match the device output to the OEM's reference calculation. Alternatively, the factory could supply the reference digest for the factory keys, and this could be incorporated by the user into the overall hash calculation. However, for other uses, such as confirming the contents of the device haven't changed from the point in time when a reference digest is calculated and internally stored, to a later time when it is checked, all static data may be included, even if the source data, known to the device, is unknown to the user. The data used by the device in the digest calculations can be either the as-received data, or the as-programmed (and verified) data, though the later is generally preferable as it ensures the integrity of the programming operation as well as the receipt of the correct data transmission. It is also possible to perform the calculation on both the as-received data and the as-programmed data to differentiate between a transmission or programming error (whether naturally or maliciously-induced).

The overall digest resulting from the combination of the partial digests is a representation of the data to be input to the PLD device. As may be seen from the use of the FSN the uniquified digest output from reference numeral 88 is different for each device. In this manner, the entire population of a particular lot of PLD devices may be individually controlled.

A “certificate” may be created for the individual PLD by performing the function MAC{ } at reference numeral 90 on the uniquified digest that is computed at reference numeral 88 by circuitry within the PLD once the lock bit or bits are set, generating the encrypted digest, or MAC. The completed certificate includes the MAC and the device's FSN, and optionally other data such as the overall plaintext digest output by reference numeral 80, or digests of individual sections. The encrypted digest (or MAC) is keyed for security, so it cannot be forged by someone not knowing the key. The “Key” for the encrypted digest, reference numeral 92, used to generate the certificate from the uniquified digest is a shared key known by the device and the OEM. One choice of key for reference numeral 92 is the key that was used to encrypt the bitstream by the OEM, and therefore used by the device to decrypt the bitstream before programming the plaintext configuration data. Different choices of key could be used for different sections of data, or at different times, or for different devices, but whatever the choice of key is, it should not be known by the vendor (or other actor) who's work is being verified, otherwise that actor may be able to forge certificates that compare correctly while maliciously programming different data into the device(s).

In the controlled and trusted environment, reference numeral 62, the overall digest at reference numeral 86 is created by digesting the appropriate sections of data using the EDA tool, which parallels the computation of the overall digest within the device up to the output of reference numeral 80. This overall digest can be exported for use by the vendor in a quick check on the integrity of the programmed data as discussed above with reference to numeral 84. Up to reference numeral 80, some or all of the data, may be common to a large population of devices, and so the parallel computations in the EDA tool can be shared for greater efficiency, as in reference numeral 86. The FSN received from reference numeral 64 is used in the EDA tool at reference numeral 94 in combination with the output of reference numeral 86 to generate a reference uniquified digest for each individual device, but this computation is relatively low complexity compared to the digest calculation of the large mass of PLD configuration data accomplished at reference numeral 86. The MAC is computed at reference numeral 96 by incorporating both the reference uniquified digest output by reference numeral 94 and the shared key 92, which has the same value as the key 92 used by the device.

The FSN at reference numeral 64 and the MAC output of reference numeral 90 concatenated together comprise the certificate for the PLD, which is returned to the original equipment manufacturer. The factory public serial number (FSN) field is extracted from the concatenated whole and can be used in calculating the reference encrypted digest (MAC) by the manufacturer, reference number 96. The MAC output from reference numeral 90 in the device can be compared in the controlled and trusted environment 62 at reference numeral 98 with the MAC output from reference numeral 96. If the encrypted digest received from the PLD device 60 equals the encrypted digest computed by the EDA tool in the controlled and trusted environment 62, the programming operation of the PLD device is confirmed. Such a confirmation further indicates that the lock bit or bits in the PLD have been set, since these are set as part of reference numeral 68, and this assures that the entity that performed the programming is locked out from altering the programming in any way.

Parts of the reference calculation, performed in controlled and trusted environment, reference numeral 62, such as computation of the reference digest, reference number 86, may be computed well in advance of actual device programming. Other portions, for example the steps indicated by reference numerals 94 and 96 may be also be computed before device programming if the device serial numbers are known or may be predicted, but it may be more convenient to do at roughly the same time, or after the devices are programmed. The comparison, reference numeral 98, is done after the devices are programmed and they have generated their individual certificates.

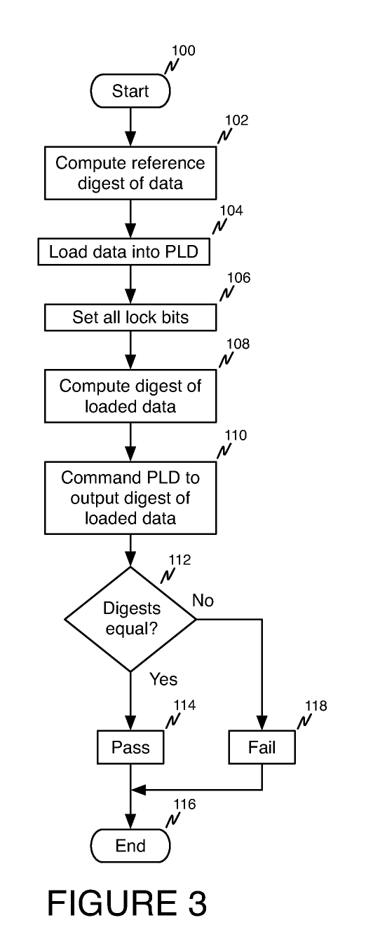

Referring now to FIG. 3, a flow diagram shows the operation of one illustrative embodiment of the present invention. The method begins at reference numeral 100. At reference numeral 102, a reference digest of the data to be loaded into the PLD is computed. This operation may be performed by the EDA tool supplied by the manufacturer. The reference digest may be encrypted for security purposes. At reference numeral 104, data is loaded into the PLD. The data loaded may also be encrypted, and in one embodiment, the same or a related key is used for computing the reference digest as is used for encrypting the loaded data. At reference numeral 106, the lock bit or bits are set in the PLD, preventing further programming.

At reference numeral 108, the PLD is commanded to compute a digest of the loaded data. The digest may be encrypted inside the PLD prior to being output by the PLD using the same key as used in generating the encrypted reference digest.

The digest output by the PLD is then transmitted to the manufacturer or the OEM who purchased the device who then compares the transmitted digest with the reference digest at reference numeral 112. If the reference digest and the PLD output are equal, the device passes at reference numeral 114 and the process ends at reference numeral 116. If the reference digest and the PLD output are not equal, the device fails at reference numeral 118 and the process ends at reference numeral 116. If the device fails, this could indicate either a programming error or that some of the data has been tampered with by the entity programming the device.

In instances where an entire lot of PLDs are being programmed, the EDA tools generate a separate reference digest for each individual PLD by repeating the computations and in each instance using a different serial number from among all of the serial numbers in the lot of PLDs.

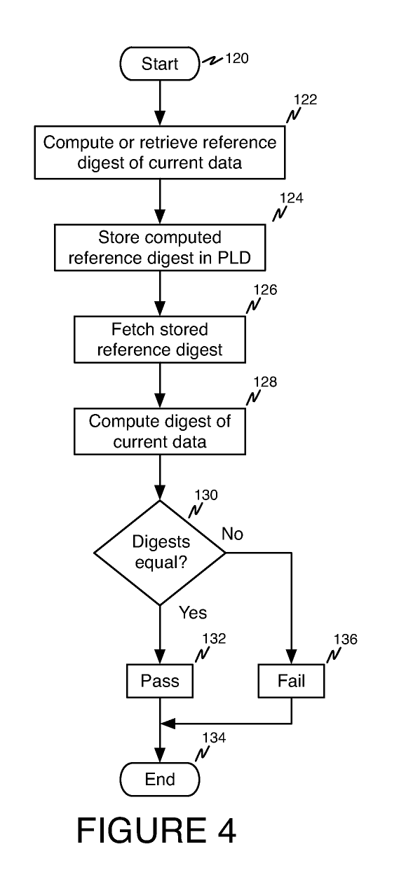

Referring now to FIG. 4, a flow diagram shows the operation of another illustrative embodiment of a method according to the present invention. The method begins at reference numeral 120. At reference numeral 122, a reference digest of the data initially programmed into the PLD is computed. This operation may be performed by the EDA tool supplied by the manufacturer. The reference digest may be encrypted for security purposes. At reference numeral 124, the computed reference digest is stored on non-volatile memory on the chip containing the PLD.

At any later time, at reference numeral 126, the reference digest is retrieved from memory. At reference numeral 128, the PLD is commanded to compute a digest of the current data. Persons of ordinary skill in the art will appreciate that the order in which the processes of reference numerals 126 and 128 are performed is not critical.

At reference numeral 130, the reference digest and the digest of current data are compared. If the reference digest and the digest of current data in the PLD are equal, the device passes at reference numeral 132 and the process ends at reference numeral 134. If the reference digest and the digest of current data in the PLD output are not equal, the device fails at reference numeral 136 and the process ends at reference numeral 134. If the device fails, this could indicate either a programming error or that one or more memory cell locations have failed.

According to other aspects of the present invention, several variations of the above-described method are possible. First, the digest can be run against selected portions of the FPGA data, as opposed to all the data in the device. In some cases, the OEM may not know all the data. For example, the OEM would not know the manufacturer's factory keys, and thus these need to be excluded from any calculation that the OEM would run in its EDA tools. In some applications, the programming process may be performed in stages. In those applications, the digest may only be run against the latest data set or portions thereof that have been programmed into the device.

There is also the matter of computational efficiency. In practice, many PLDs are often programmed with the same bitstream. Often, only the FSN and the keys are different over a large number of devices. The configuration bitstream including the PLD configuration data is the largest amount of data stored in the PLD, so computing the digest in the EDA tool for this portion of the data would typically take the longest time. However, since this data is the same in the total population of PLDs, it can be computed just once. This calculated digest for the configuration bitstream can then be used in the calculation of the final digest value for all the FPGAs by combining it with the digest for the other parts of the FPGA that may be unique in each device (such as the FSN). In one way to make this scheme work, the different parallel partial digest calculations may be combined in a commutative-associative manner. Another way to make this work is for the FPGA fabric, if included in the digest, to always be the first part of the total message being iteratively hashed.

Another enhancement, related to the first, is that the final digest value is preferably encrypted. If the certificate can be run at will for any part(s) of the FPGA, and if the parts are combined using a publicly known hashing algorithm, then it is preferred that the result be encrypted, otherwise a malicious agent could discover the expected digest value for all the parts of the FPGA individually, and then forge a “correct” digest value to be sent to the OEM, while the parts built are actually different. It is preferable that no one be able to predict the correct digest/certificate for any given device. Encryption of the combined digest result prevents this attack.

There are several ways to determine the key to be used for encrypting the digest. A key stored in the FPGA can be used directly. This could be a shared key installed by the device manufacturer or the OEM user. Alternatively, an ephemeral key known to the device and the OEM can be used. This could be the result of transporting a symmetric key into the device, or the result of a public-key/private key establishment method.

While embodiments and applications of this invention have been shown and described, it would be apparent to those skilled in the art that many more modifications than mentioned above are possible without departing from the inventive concepts herein. The invention, therefore, is not to be restricted except in the spirit of the appended claims.

What is claimed is:

1. A method for verifying that data is correctly loaded into an individual programmable logic device, comprising:
computing a reference digest of at least a portion of the data for the individual programmable logic device;
loading the data into the individual programmable logic device;
computing inside the individual programmable logic device a device digest of the at least the portion of the data that was loaded into the individual programmable logic device;
reading the device digest out of the individual programmable logic device;
comparing the device digest with the reference digest; and
verifying the loaded data if the device digest matches the reference digest, and indicating an error if the device digest does not match the reference digest.

2. The method of claim 1 wherein the portion comprises the complete data for the individual programmable logic device.

3. The method of claim 1, further including encrypting the device digest prior to reading the device digest out of the individual programmable logic device.

4. The method of claim 1 wherein;
the data for the individual programmable logic device includes common configuration data and data unique to the individual programmable logic device;
computing a reference digest of the data to be loaded into the individual programmable logic device further includes computing a first partial reference digest of common configuration data to be loaded into the individual programmable logic device, and computing the reference digest by combining the first partial reference digest with information unique to the individual programmable logic device; and
computing inside the individual programmable logic device a device digest of the configuration data that was loaded into the individual programmable logic device includes computing a first partial device digest of the common configuration data that was loaded into the individual programmable logic device, and computing the device digest by combining the first partial device reference digest with information unique to the individual programmable logic device.

5. The method of claim 4 wherein the data unique to the individual programmable logic device includes serial number data preprogrammed into the programmable logic device.

6. The method of claim 4 wherein the common configuration data is the first part of the total data being computed into the reference digest and the data unique to the individual programmable logic device is the second part of the total data being computed into the reference digest.

7. A method for verifying that at least a portion of the data stored in an individual programmable logic device has not become corrupted, comprising:
computing a reference digest of the at least a portion of the data stored in the individual programmable logic device;
computing inside the individual programmable logic device a current digest of the at least the portion of the data currently stored in the individual programmable logic device;
comparing the current digest with the reference digest; and
verifying the loaded data if the current digest matches the reference digest, and indicating the data has become corrupted if the current digest does not match the reference digest.

8. The method of claim 7 wherein:
the individual programmable logic device includes common configuration data and data unique to the individual programmable logic device;
the computing of the reference digest further includes computing a reference digest of the common configuration data loaded into the individual programmable logic device combined with computing a reference digest of the data unique to the individual programmable logic device; and
computing the current digest of the configuration data loaded into the individual programmable logic device further includes computing a current digest of the current common configuration data loaded into the individual programmable logic device combined with computing a current digest of the data as-programmed unique to the individual programmable logic device.

9. The method of claim 8 wherein the data unique to the individual programmable logic device includes serial number data preprogrammed into the programmable logic device.

10. The method of claim 7 wherein the common configuration data is the first part of the total data being computed into the reference digest and the data unique to the individual programmable logic device is the second part of the total data being computed into the reference digest.

11. The method of claim 7, further including reading the as-programmed digest out of the individual programmable logic device.

12. The method of claim 11, further including encrypting the as-programmed digest prior to reading the as-programmed digest out of the individual programmable logic device.

13. The method of claim 7 further including storing the reference digest in the programmable logic device.
